(19) United States
(12) Patent Application Publication
(10) Pub. No.: US 2025/0070535 A1
(43) Pub. Date: Feb. 27, 2025

(54) INDIVIDUALLY-ADDRESSABLE OPTICAL EMITTER ARRAY

(71) Applicant: Lumentum Operations LLC, San Jose, CA (US)

(72) Inventor: Albert YUEN, Palo Alto, CA (US)

(21) Appl. No.: 18/508,468

(22) Filed: Nov. 14, 2023

Related U.S. Application Data
(60) Provisional application No. 63/578,559, filed on Aug. 24, 2023.

(51) Int. Cl. H01S 5/183; H01S 5/042; H01S 5/42

(52) U.S. Cl. CPC H01S 5/18305; H01S 5/04254; H01S 5/04256; H01S 5/423

(57) ABSTRACT

In some implementations, an optical module includes a plurality of bottom-emitting vertical cavity-surface emitting lasers (VCSELs), a plurality of anodes corresponding to and connected to the plurality of VCSELs; and a single cathode connected to the plurality of optical emitters, wherein the single cathode is paired with each anode of the plurality of anodes.

### CROSS-REFERENCE TO RELATED APPLICATION

This Patent Application claims priority U.S. Provisional Patent Application No. 63/578,559, filed on Aug. 24, 2023, and entitled “VERTICAL CAVITY SURFACE EMITTING LASER ARRAYS.” The disclosure of the prior Application is considered part of and is incorporated by reference into this Patent Application.

### TECHNICAL FIELD

The present disclosure relates generally to optical emitters and to an individually-addressable array of bottom-emitting vertical cavity surface emitting lasers (VCSELs).

### BACKGROUND

An optical emitter device, such as a vertical cavity surface emitting laser (VCSEL), may include a laser, an optical transmitter, and/or the like in which a beam is emitted in a direction perpendicular to a surface of a substrate (e.g., vertically from a surface of a semiconductor wafer). Multiple optical emitter devices may be arranged in one or more emitter arrays (e.g., VCSEL arrays) on a common substrate.

### SUMMARY

In some implementations, an optical module includes a plurality of bottom-emitting vertical cavity-surface emitting lasers (VCSELs), a plurality of anodes corresponding to and connected to the plurality of VCSELs; and a single cathode connected to the plurality of optical emitters, wherein the single cathode is paired with each anode of the plurality of anodes.

In some implementations, an optical module includes a plurality of optical emitters, an optical emitter, of the plurality of optical emitters, comprising: a lower distributed Bragg reflector (DBR), a plurality of anodes corresponding to and connected to the plurality of optical emitters; and one or more cathodes connected to the plurality of optical emitters,

In some implementations, an optical module includes a plurality of optical emitters, an optical emitter, of the plurality of optical emitters, comprising: a lower distributed DBR, a plurality of p-pads corresponding to and connected to the plurality of optical emitters; and a single n-pad connected to the plurality of optical emitters and paired with the plurality of p-pads.

### BRIEF DESCRIPTION OF THE DRAWINGS

FIGS. 1A and 1B are diagrams depicting an example emitter, respectively.

FIG. 2 is a diagram of an example optical module associated with an individually-addressable optical emitter array.

FIGS. 3A-3C are diagrams of example implementations associated with an individually-addressable optical emitter array.

### DETAILED DESCRIPTION

The following detailed description of example implementations refers to the accompanying drawings. The same reference numbers in different drawings may identify the same or similar elements.

Multiple optical emitters, such as vertical cavity surface emitting lasers (VCSELs) may be arranged to form an array. For example, multiple bottom-emitting VCSELs may form a VCSEL array, such as a linear emitter array (e.g., where multiple bottom-emitting VCSELs are aligned in a linear arrangement and have a uniform or non-uniform spacing), a grid emitter array (e.g., where multiple bottom-emitting VCSELs are uniformly spaced in two dimensions and oxidation trenches may be shared by two or more emitters) or a non-grid emitter array (e.g., where multiple emitters are not uniformly spaced in two dimensions and each emitter requires a set of oxidation trenches that may or may not be shared), among other examples.

In such arrangements, VCSEL-to-VCSEL pitch (e.g., a spacing between respective center points of each VCSEL) may be approximately 250 micrometers (μm), which may match a corresponding parallel fiber array. However, a density of an approximately 250 um pitch for VCSELs may be insufficient for increasingly miniaturized optical systems. Additionally, or alternatively, increasingly miniaturized and dense optical systems may have power dissipation requirements and speed requirements that cannot be achieved by a VCSEL array with a pitch of approximately 250 μm.

Some implementations described herein provide an optical module with shared components. For example, an optical module may include multiple bottom-emitting VCSELs that share a single cathode. In this way, by sharing a cathode across multiple bottom-emitting VCSELs, a VCSEL array may achieve a pitch of less than 250 μm, less than 100 μm, less than 50 μm, or less than 10 μm, among other examples. Additionally, or alternatively, the optical module may include multiple anodes corresponding to the multiple bottom-emitting VCSELs. In this way, by having multiple anodes paired with a shared cathode, the VCSEL array achieves a pitch reduction while also enabling each VCSEL, of the VCSEL array, to be individually addressed and/or activated by a controller or control component. In some implementations, the optical module may have the shared cathode surrounded by the individual anodes in a lattice arrangement, such as a hexagonal close pack arrangement, which may enable a high level of density (e.g., a pitch of approximately 10 μm) in an individually addressable VCSEL array. Further, by a density of VCSELs within a VCSEL array of an optical module being improved, the optical module can achieve high data rates from a high density of low data rate VCSELs. In other words, rather than using relatively high data rate VCSELs in a low density array, which may result in high power dissipation requirements for the optical module, the optical module may use relatively low data rate VCSELs in a high density array, which may result in relatively low power dissipation requirements for the optical module, to achieve the same or a higher net data rate.

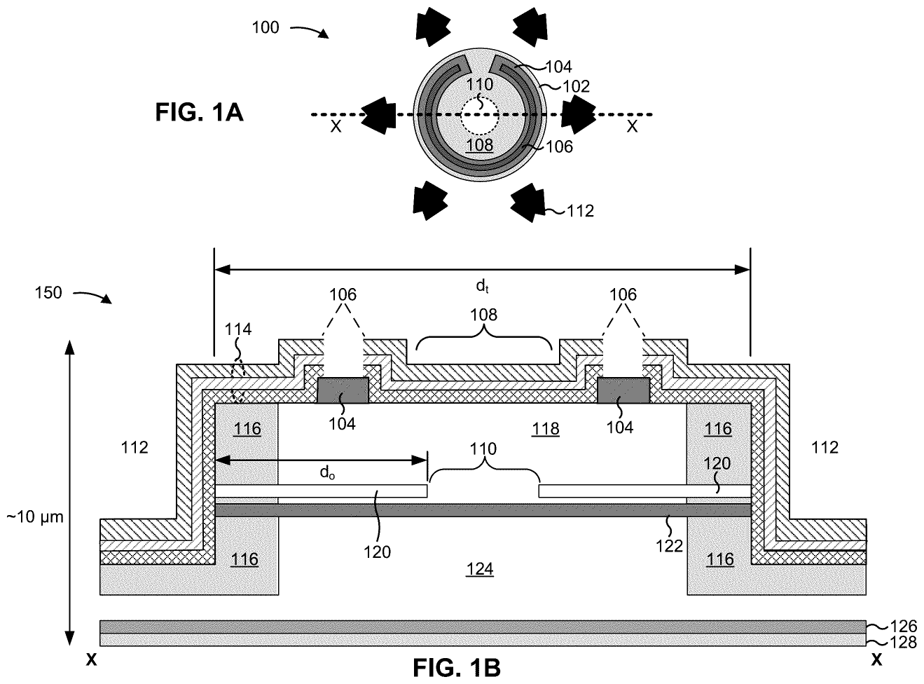

FIGS. 1A and 1B are diagrams depicting a top view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). A first area of ohmic metal layer 104 is covered by a protective layer (e.g., a dielectric layer or a passivation layer) of emitter 100 and a second area of ohmic metal layer 104 is exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). A first area shows a portion of ohmic metal layer 104 that is exposed by via 106 (e.g., the shape of the first area may be a result of the shape of via 106) while a second area shows a portion of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dt. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al2O3 layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al2O3 layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

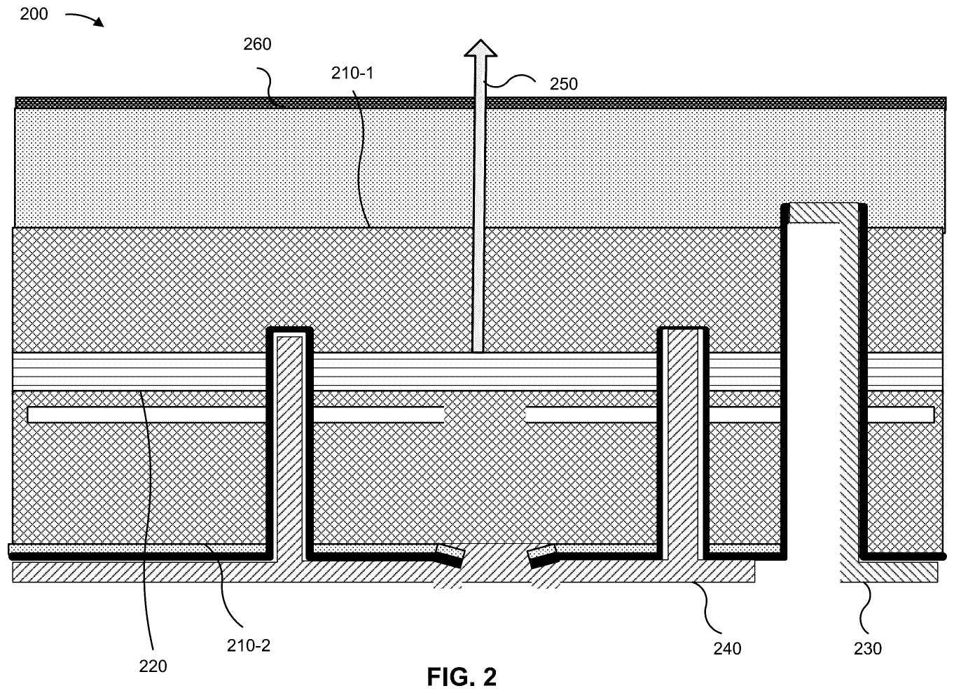

FIG. 2 is a diagram of an example optical module 200 associated with an individually-addressable optical emitter array.

As shown in FIG. 2, example optical module 200 includes a first distributed Bragg reflector (DBR) 210-1 (e.g., an upper DBR) and a second DBR 210-2 (e.g., a lower DBR) that sandwich an active region 220. The DBRs 210 and the active region 220 form an optical emitter that is addressable by control of, for example, a cathode and an anode. As further shown in FIG. 2, the example optical module 200 includes a shared cathode pad 230 and one or more anode pads 240. A cathode pad 230 may include a negative doped (N-doped) material, which may be referred to as an “n-pad”. Similarly, an anode pad 240 may include a positive doped (P-doped) material, which may be referred to as a “p-pad”. The cathode pad 230 and the anode pad 240 are configured to receive, respectively, a cathode and an anode. For example, a cathode may be disposed on the cathode pad 230 and controlled by a controller (not shown) and an anode may be disposed on the anode pad 240 and controlled by the controller. In this case, the controller may be provided in the optical module 200 or connected to the optical module 200 to apply a signal (e.g., an electrical current) to a cathode pad 230 and/or an anode pad 240. The optical module 200 may emit an optical beam 250, which may extend out from a substrate 260. In some implementations, emitters of the optical module 200 (or emitters of a group of optical modules 200) may emit multiple optical beams 250.

In some implementations, each optical emitter of the optical module 200 may be a low data rate optical emitter for emitting an optical beam 250 or a component of an optical beam 250. For example, by achieving a high density of optical emitters, the optical module can achieve a threshold data rate using a dense arrangement of low data rate optical emitters. In this example, the optical emitters may each have a data rate of less than a threshold, such as less than 1 gigabit per second (Gb/s), less than 10 Gb/s, or less than 25 Gb/s, among other examples. In this way the optical module 200 reduces a power dissipation. Additionally, or alternatively, by using low data rate optical emitters, the optical module 200 may be enabled to use lower complexity optical emitters or lower complexity or lower performance optical drivers for the optical emitters, among other examples. Additionally, or alternatively, by using low data rate optical emitters, the optical module 200 may obviate a need for some components, such as obviating a need for a digital signal processor (DSP) or a clock and data recovery (CDR) component. In this case, the optical module may use a non-return-to-zero (NRZ) modulation scheme and/or direct drive from an application-specific integrated circuit (ASIC), rather than using, for example, a pulse amplitude modulation 4-level (PAM4) modulation scheme with digital signal processing. Alternatively, the optical module 200 may use high data rate optical emitters, DSPs, CDR components, and/or higher complexity modulation schemes with a dense array of optical emitters to achieve higher data rates and/or greater miniaturization than is achievable with less dense arrays of optical emitters. For example, the optical module 200 may include optical emitters that have a data rate greater than or equal to a threshold, such as greater than 1 Gb/s, greater than 10 Gb/s, or greater than 25 Gb/s, among other examples.

In some implementations, each optical emitter of the optical module 200 may be associated with a different anode pad 240. For example, the optical module 200 may include a plurality of pairs of DBRs 210 and a plurality of corresponding active regions 220, each of which may have an individual anode pad 240. In this example, a first optical emitter (e.g., a first pair of DBRs 210 and a corresponding active region 220) and a second optical emitter (e.g., a second pair of DBRs 210 and a corresponding active region 220) may share a cathode pad 230 in common. In some implementations, one or more anode pads 240 may be shared by multiple optical emitters of the optical module 200. For example, a first optical emitter (e.g., a first pair of DBRs 210 and a corresponding active region 220) and a second optical emitter (e.g., a second pair of DBRs 210 and a corresponding active region 220) may share a single anode pad 240 (and may have the same or different cathode pads 230).

In some implementations, all optical emitters of the optical module 200 may share a single cathode pad 230. For example, the single cathode pad 230 may have a single cathode that is connected to each optical emitter (e.g., each pair of DBRs 210 and corresponding active region 220). Additionally, or alternatively, some groups of optical emitters may be associated with different cathode pads 230. For example, a first group of optical emitters (e.g., a first group of pairs of DBRs 210 and corresponding active regions 220) may share a first cathode pad 230 and a second group of optical emitters (e.g., a second group of pairs of DBRS 210 and corresponding active regions 220) may share a second cathode pad 230. In some examples, the first group of optical emitters and the second group of optical emitters may be disjoint. In other words, each cathode pad 230 may be associated with a group of two or more anode pads 240 that is unique to the cathode pad 230. Alternatively, the first group of optical emitters and the second group of optical emitters may overlap. In other words, one or more anode pads 240 may be associated with both the first cathode pad 230 and the second cathode pad 230.

In some implementations, the optical module 200 may be included in or coupled to an optical system. For example, the optical module 200 may be included in or coupled to an optical communication system, an optical sensing system, an optical measurement system, or an optical manufacturing system, among other examples. Additionally, or alternatively, components of the optical module 200 may be coupled to components of an optical system. For example, optical emitters of the optical module 200 may be coupled into optical fibers or to an optical detector array (e.g., a set of photodetectors). In this example, the optical emitters of the optical module 200 may be coupled using free-space optics or fiber optics.

Although some implementations are described herein in terms of a particular example of a bottom-emitting VCSEL, it is contemplated that other implementations are possible, such as other configurations for a bottom-emitting VCSEL, other types of bottom-emitters, non-bottom-emitting VCSELs, or other types of emitters.

As indicated above, FIG. 2 is provided as an example. Other examples may differ from what is described with regard to FIG. 2. The number and arrangement of devices shown in FIG. 2 are provided as an example. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) shown in FIG. 2 may perform one or more functions described as being performed by another set of devices shown in FIG. 2.

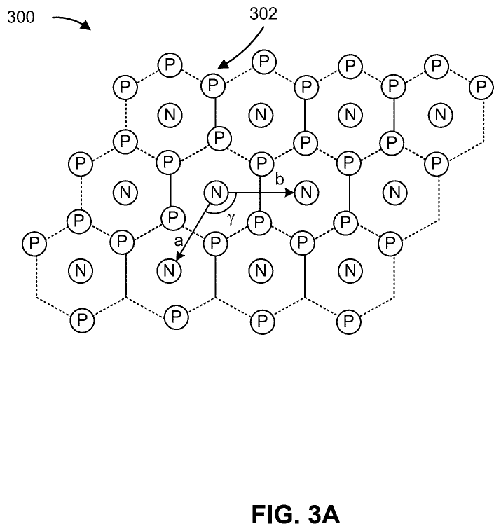

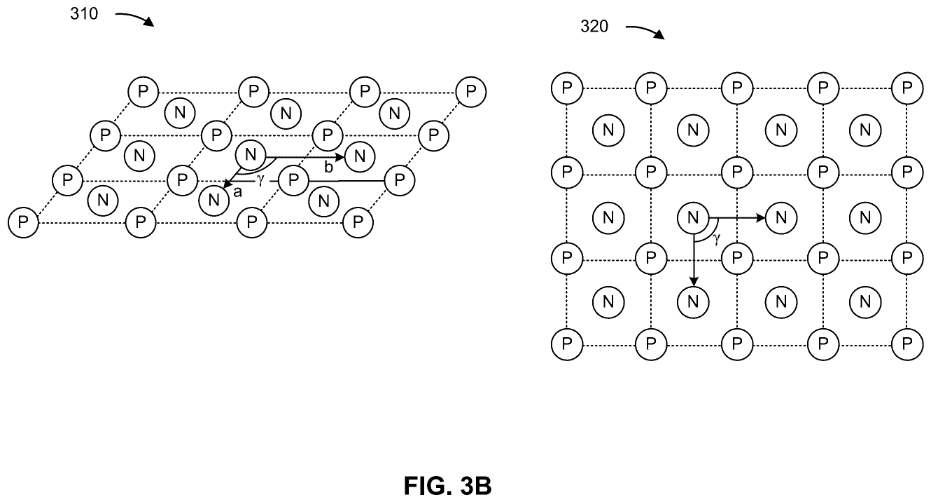

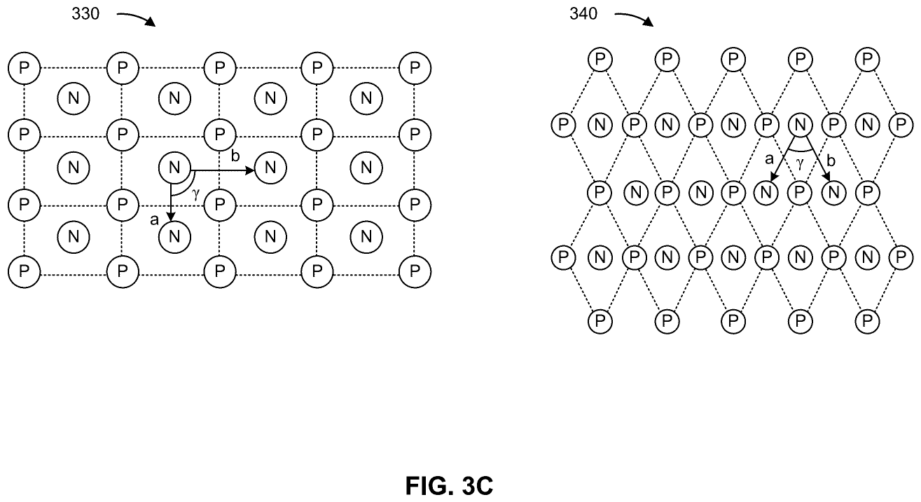

FIGS. 3A-3C are diagrams of example implementations associated with an individually-addressable optical emitter array.

FIG. 3A shows an example of a first arrangement 300 of anodes and cathodes in an optical module, as described herein (e.g., the optical module 200 of FIG. 2). The first arrangement 300 includes a hexagonal lattice arrangement. The hexagonal lattice may include n-pads that are separated along an x-axis by a pitch b and along a y-axis with a pitch a, where a=b. Further, the hexagonal lattice may have an angle between n-pads, which are adjacent to a particular n-pad, of γ, where γ=120°. For example, in the first arrangement 300, an n-pad for a cathode is surrounded by 6 p-pads for anodes. As shown, different n-pads may share different p-pads. For example, a p-pad 302 is shared by two different n-pads. In this example, a control signal to the two-different n-pads and/or the p-pad 302 (e.g., an electrical current that is applied) may be used to individually control the p-pad 302. In some implementations, the hexagonal lattice (or an approximation thereof) may be selected to achieve a highest level of density of emitters.

In some implementations, an arrangement of anodes and cathodes, such as the first arrangement 300, may have a particular density (e.g., a pitch of less than a particular value). For example, an optical module described herein may have a pitch (e.g., a or b) of less than 250 μm, less than 200 μm, less than 100 μm, less than 50 μm, less than 25 μm, or less than 10 um. Although some implementations are described in terms of anodes and cathodes for an optical emitter, implementations described herein may achieve less than a threshold pitch for another type of optical device, such as for a detector array.

FIG. 3B shows examples of arrangements 310-320 of anodes and cathodes in an optical module, described herein (e.g., the optical module 200 of FIG. 2). A second arrangement 310 includes an oblique lattice. In the oblique lattice, an n-pad is associated with a pitch b along an x-axis and a pitch a along a y-axis, where a≠b. Further, in the oblique lattice, an angle between n-pads, which are adjacent to a particular n-pad, is γ, where γ>0°. A third arrangement 320 includes a square lattice in which a=b and γ=90°. FIG. 3C shows examples of arrangements 330-340 of anodes and cathodes in an optical module, as described herein (e.g., the optical module 200 of FIG. 2). A fourth arrangement 330 includes a rectangular lattice in which a≠b and γ=90°. A fifth arrangement 340 includes a rhombic lattice in which a=b and γ>0°.

Although two-dimensional regular lattice arrangements are described herein, other arrangements may be used. For example, an arrangement of n-pads and p-pads may be in the form of an irregular two-dimensional lattice. Additionally, or alternatively, an arrangement of n-pads and p-pads may be in the form of one or more one-dimensional linear arrangements. Additionally, or alternatively, an arrangement of n-pads and p-pads may be in the form of a three-dimensional lattice (e.g., a regular or irregular lattice). For example, multiple lattices may be stacked on top of each other such that each emitter can emit in gaps between other emitters of a lattice. Additionally, or alternatively, although certain quantities of n-pads and p-pads are described herein, various implementations may be used for other quantities of n-pads and p-pads, such as a one-dimensional array of 1×4 or 1×12 optical emitters, a two-dimensional array of 2×2, 4×4, 16×16, 2×8, or 4×12 optical emitters, or a three-dimensional array of 2×2×2, 4×4×4, or 2×8×8 optical emitters, or another combination.

As indicated above, FIGS. 3A-3C are provided as an example. Other examples may differ from what is described with regard to FIGS. 3A-3C. The number and arrangement of devices shown in FIGS. 3A-3C are provided as an example. In practice, there may be additional devices, fewer devices, different devices, or differently arranged devices than those shown in FIGS. 3A-3C. Furthermore, two or more devices shown in FIGS. 3A-3C may be implemented within a single device, or a single device shown in FIGS. 3A-3C may be implemented as multiple, distributed devices. Additionally, or alternatively, a set of devices (e.g., one or more devices) shown in FIGS. 3A-3C may perform one or more functions described as being performed by another set of devices shown in FIGS. 3A-3C.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical module, comprising:
a plurality of bottom-emitting vertical cavity-surface emitting lasers (VCSELs),
a plurality of anodes corresponding to and connected to the plurality of bottom-emitting VCSELs; and
a single cathode connected to the plurality of bottom-emitting VCSELs,
wherein the single cathode is paired with each anode of the plurality of anodes.

2. The optical module of claim 1, further comprising:
a control component to individually control each anode of the plurality of anodes.

3. The optical module of claim 1, wherein plurality of anodes is arranged in a hexagonal lattice arrangement around the single cathode.

4. The optical module of claim 1, wherein the plurality of anodes is arranged, around the single cathode, in at least one of:
an oblique lattice,
a square lattice,
a rectangular lattice, or
a rhombic lattice.

5. The optical module of claim 1, wherein plurality of anodes is arranged in a linear arrangement around the single cathode.

6. The optical module of claim 1, wherein a spacing between a first bottom-emitting VCSEL, of the plurality of bottom-emitting VCSELs, and a second bottom-emitting VCSEL, of the plurality of bottom-emitting VCSELs, is less than approximately 250 micrometers.

7. The optical module of claim 1, wherein a spacing between a first bottom-emitting VCSEL, of the plurality of bottom-emitting VCSELs, and a second bottom-emitting VCSEL, of the plurality of bottom-emitting VCSELs, is less than approximately 50 micrometers.

8. An optical module, comprising:
a plurality of optical emitters,
an optical emitter, of the plurality of optical emitters, comprising:
a lower distributed Bragg reflector (DBR),
an upper DBR,
an active region disposed between the lower DBR and the upper DBR,
wherein the plurality of optical emitters includes a plurality of vertical cavity surface emitting lasers (VCSELs),
wherein the plurality of VCSELs is a plurality of bottom-emitting VCSELS;
a plurality of anodes corresponding to and connected to the plurality of optical emitters; and
one or more cathodes connected to the plurality of optical emitters,
wherein each cathode, of the one or more cathodes, is paired with a corresponding two or more anodes of the plurality of anodes.

9. The optical module of claim 8, wherein a first cathode, of the one or more cathodes, is paired with a first set of two or more anodes of the plurality of anodes, and wherein a second cathode, of the one or more cathodes, is paired with a second set of two or more anodes of the plurality of anodes.

10. The optical module of claim 9, wherein the first set of two or more anodes is disjoint from the second set of two or more anodes.

11. The optical module of claim 9, wherein at least one anode, of the plurality of anodes, is included in the first set of two or more anodes and is included in the second set of two or more anodes.

12. The optical module of claim 8, wherein each set of two or more anodes, of the plurality of anodes, is arranged in a ring around a corresponding cathode of the one or more cathodes.

13. The optical module of claim 12, wherein the ring forms a hexagonal close pack arrangement.

14. The optical module of claim 8, further comprising:
a controller to control the plurality of anodes and the one or more cathodes to individually activate each optical emitter of the plurality of optical emitters.

15. The optical module of claim 8, further comprising:
a plurality of fibers to receive a plurality of beams from the plurality of optical emitters.

16. The optical module of claim 8, further comprising:
a detector array to receive a plurality of beams from the plurality of optical emitters.

17. An optical module, comprising:
a plurality of optical emitters,
an optical emitter, of the plurality of optical emitters, comprising:
a lower distributed Bragg reflector (DBR),
an upper DBR,
an active region disposed between the lower DBR and the upper DBR;
a plurality of p-pads corresponding to and connected to the plurality of optical emitters; and
a single n-pad connected to the plurality of optical emitters and paired with the plurality of p-pads.

18. The optical module of claim 17, wherein the plurality of p-pads includes a plurality of positive doped material areas disposed on a substrate.

19. The optical module of claim 17, wherein the single n-pad is a single negative doped material area disposed on a substrate.

20. The optical module of claim 17, wherein the plurality of optical emitters are each configured for less than a threshold data rate.
